(19) United States
(12) Patent Application Publication
(10) Pub. No.: US 2026/0334300 A1
(43) Pub. Date: Oct. 22, 2026

(54) SEMICONDUCTOR DEVICE AND METHOD OF MANUFACTURING SEMICONDUCTOR DEVICE

(71) Applicant: SUMITOMO ELECTRIC DEVICE INNOVATIONS, INC., Yokohama-shi (JP)

(72) Inventor: Takashi KITAWADA, Kanagawa (JP)

(73) Assignee: SUMITOMO ELECTRIC DEVICE INNOVATIONS, INC., Yokohama-shi (JP)

(21) Appl. No.: 19/644,004

(22) Filed: Apr. 10, 2026

(30) Foreign Application Priority Data
Apr. 16, 2025 (JP) 2025-067704

(51) Int. Cl. H10W 76/13; H10W 76/67

(52) U.S. Cl. CPC H10W 76/13; H10W 76/67

(57) ABSTRACT

A semiconductor device includes a semiconductor element, a package base having a mounting surface on which the semiconductor element is disposed and a first side wall surrounding the semiconductor element, the first side wall having a top surface, a cap disposed on the package base to form a closed hollow portion between the cap and the package base and to house the semiconductor element in the hollow portion, and having a second side wall facing the first side wall of the package base, the second side wall having a top surface facing the top surface of the package base, and an adhesive provided between the top surface of the first side wall and the top surface of the second side wall to adhere the first side wall to the second side wall.

### CROSS REFERENCE TO RELATED APPLICATION

This application claims priority based on Japanese Patent Application No. 2025-067704 filed on Apr. 16, 2025, and the entire contents of the Japanese patent application are incorporated herein by reference.

### TECHNICAL FIELD

The present disclosure relates to a semiconductor device and a method of manufacturing a semiconductor device.

### BACKGROUND

A semiconductor device in which a semiconductor element such as a field effect transistor (FET) is hermetically housed in a package is known. The package includes a package base and a cap (also referred to as a lid). The package base has a mounting surface on which the semiconductor element is disposed, and a side wall surrounding the semiconductor element. The cap is disposed on the package base to form a closed hollow portion between the cap and the package base, and the semiconductor element is housed in the hollow portion.

As a structure for attaching the cap to the package base, generally, an adhesive is applied to the adhesive surface of the cap in advance, the cap is disposed on the package base, and the adhesive is cured. However, due to certain factors, the gas in the hermetically-sealed package may expand to increase the internal pressure of the package, and the gas in the package may blow out to the outside of the package by passing through the uncured adhesive. When such a phenomenon occurs, an opening, which is a trace of the gas blowing out, remains as a through hole even after the adhesive is cured. Thus, the air-tightness of the package is impaired.

In a structure described in patent literature (Japanese Unexamined Patent Application Publication No. 2001-053179), a hole is formed in the cap, and a sheet having adhesiveness and flexibility is attached as a leak valve so as to close the hole. In this structure, when the internal pressure of the package rises, the gas in the package escapes to the outside of the package through the hole, and thus, the gas in the package is prevented from blowing out through the adhesive.

### SUMMARY

A semiconductor device according to an embodiment of the present disclosure includes a semiconductor element, a package base having a mounting surface on which the semiconductor element is disposed and a first side wall surrounding the semiconductor element, the first side wall having a top surface, a cap disposed on the package base to form a closed hollow portion between the cap and the package base and to house the semiconductor element in the hollow portion, and having a second side wall facing the first side wall of the package base, the second side wall having a top surface facing the top surface of the package base, and an adhesive provided between the top surface of the first side wall and the top surface of the second side wall to adhere the first side wall to the second side wall. At least one of the top surface of the first side wall or the top surface of the second side wall includes a portion extending in a first direction. The portion includes a first region whose width in a second direction orthogonal to the first direction has a first size, and at least one second region whose width in the second direction has a second size larger than the first size.

### BRIEF DESCRIPTION OF THE DRAWINGS

FIG. 1 is a plan view showing a semiconductor device according to an embodiment.

FIG. 2 is a bottom plan view showing a cap and an adhesive included in the semiconductor device.

FIG. 3 is a cross-sectional view of the cap, taken along a line III-III shown in FIG. 2.

FIG. 4 is a perspective view showing a cap.

FIG. 5 is a perspective view showing a part of a cap in an enlarged manner.

FIG. 6 is a perspective view for describing an effect achieved by a semiconductor device according to an embodiment.

FIG. 7 is a perspective view for describing an effect achieved by a semiconductor device according to an embodiment.

FIG. 8 is a perspective view for describing an effect achieved by a semiconductor device according to an embodiment.

FIGS. 9A and 9B are diagrams for describing the reason that gas is more likely to be blown out at a portion where an adhesive is locally thinned.

FIG. 10 is a perspective view showing a part of a cap according to a first modification in an enlarged manner.

FIG. 11 is a perspective view showing a part of a cap according to a first modification in an enlarged manner.

FIG. 12 is a perspective view showing a part of a cap according to a second modification in an enlarged manner.

FIG. 13 is a perspective view showing a part of a cap according to a third modification in an enlarged manner.

FIG. 14 is a bottom plan view showing a cap according to a fourth modification.

FIG. 15 is a perspective view showing a package base according to a fifth modification.

FIG. 16 is a perspective view showing a part of a package base according to a fifth modification in an enlarged manner.

### DETAILED DESCRIPTION

However, in the structure described in the patent literature, there is a possibility that the air-tightness of the package may be reduced due to aging deterioration of the sheet or the like. In addition, a step of attaching the sheet to the cap is required, and the number of steps of manufacturing the semiconductor device increases.

An object of the present disclosure is to provide a semiconductor device and a method of manufacturing a semiconductor device, which can maintain air-tightness of a package without providing a sheet on a cap.

According to the present disclosure, it is possible to provide a semiconductor device and a method of manufacturing a semiconductor device, which can maintain air-tightness of a package without providing a sheet on a cap.

### Description of Embodiments of Present Disclosure

First, the contents of the embodiments of the present disclosure will be listed and described.

1 A semiconductor device according to an embodiment of the present disclosure includes a semiconductor element, a package base having a mounting surface on which the semiconductor element is disposed and a first side wall surrounding the semiconductor element, the first side wall having a top surface, a cap disposed on the package base to form a closed hollow portion between the cap and the package base and to house the semiconductor element in the hollow portion, and having a second side wall facing the first side wall of the package base, the second side wall having a top surface facing the top surface of the package base, and an adhesive provided between the top surface of the first side wall and the top surface of the second side wall to adhere the first side wall to the second side wall. At least one of the top surface of the first side wall or the top surface of the second side wall includes a portion extending in a first direction. The portion includes a first region whose width in a second direction orthogonal to the first direction has a first size, and at least one second region whose width in the second direction has a second size larger than the first size.

In the semiconductor device according to the above (1), at least one of the top surface of the first side wall or the top surface of the second side wall of the package base includes the portion extending in the first direction. The portion includes the first region whose width is small in the second direction and the second region whose width is large in the second direction. As described above, since at least one of the top surface of the first side wall or the top surface of the second side wall has the first region which is locally narrowed, a portion which is locally narrowed is also formed in the adhesive. When the internal pressure of the package rises, the gas is more likely to blow out through the thinned portion, and thus, a position where the gas blows out in the adhesive can be limited. Further, when the internal pressure of the package is lowered after the gas is blown out and the gas outside the package is sucked into the package through a trace of blowing (through hole), an uncured adhesive on the second region is drawn into the trace of blowing on the first region, and the through hole is closed with the adhesive. This makes it possible to maintain the air-tightness of the package. As described above, according to the semiconductor device according to the above (1), the air-tightness of the package can be maintained without providing the sheet on the cap.

2 In the semiconductor device according to the above (1), the at least one second region may include two second regions, and the first region may be interposed between the two second regions in the first direction. The first region and the two second regions may form a first recess in the portion, the first recess being recessed toward the hollow portion or recessed in a direction opposite to the hollow portion. In this case, a recess is also formed in the adhesive on the first recess. When the internal pressure of the package rises, the gas is more likely to blow out through the recess of the adhesive, and thus, the position where the gas blows out in the adhesive can be limited. Further, when the internal pressure of the package is lowered after the gas is blown out and the gas outside the package is sucked into the package through the trace of blowing (through hole), the uncured adhesive on a region adjacent to the first recess is drawn into the trace of blowing on the first region, and the through hole is closed with the adhesive. This makes it possible to maintain the air-tightness of the package.

3 In the semiconductor device according to the above (2), the first recess may have a planar shape that is rectangular, tapered, or semicircular. For example, when the first recess has such a shape, the blowing position of the gas in the adhesive is more easily limited, and the through hole is more likely to be closed with the adhesive when the gas is sucked into the package through the trace of blowing.

4 In the semiconductor device according to the above (2) or (3), the portion may further include a second recess that is recessed toward the hollow portion or recessed in a direction opposite to the hollow portion. In this case, since a plurality of recesses is provided in the top surface and a plurality of recesses is thereby formed in the adhesive, the gas is efficiently blown out from the inside of the package to the outside of the package, and the internal pressure of the package can be rapidly reduced.

5 In the semiconductor device according to any one of the above (1) to (4), the adhesive may include a thermosetting resin. In this case, the internal pressure of the package rises due to the temperature rise when the adhesive is cured, and the gas in the package is more likely to blow out to the outside of the package by passing through the uncured adhesive. Thus, the configuration of the semiconductor device described above is particularly effective when the adhesive contains a thermosetting resin.

6 In the semiconductor device according to any one of the above (1) to (4), the adhesive may be an epoxy-based adhesive. In this case, the adhesive is cured by drying, but even in such a case, when the internal pressure of the package rises due to a rise in the ambient temperature or the like, the gas in the package blows out to the outside of the package. Thus, the configuration of the semiconductor device described above is effective.

7 A method of manufacturing the semiconductor device is a method of manufacturing the semiconductor device according to any one of the above (1) to (6). The method includes: mounting the semiconductor element on the package base; applying the adhesive before curing to the top surface of the first side wall of the package base or the top surface of the second side wall of the cap; and mounting the cap on the package base. According to this method, the air-tightness of the package can be maintained without providing a sheet on a cap.

8 In the method of manufacturing the semiconductor device according to the above (7), the adhesive before curing may have a viscosity of 300,000 (mPa·s) to 500,000 (mPa·s) at 150°C. When the uncured adhesive has such a viscosity, the gas in the package is likely to blow out to the outside of the package when the internal pressure of the package rises, and the uncured adhesive is likely to be drawn into the trace of blowing when the gas outside the package is sucked into the package through the trace of blowing. Thus, the effect of the manufacturing method according to the above (7) can be sufficiently achieved.

9 In the method of manufacturing the semiconductor device according to the above (7), the adhesive before curing may have a viscosity of 90,000 (mPa·s) to 120,000 (mPa·s) at 24°C. As described above, when the viscosity of the adhesive is relatively small, the gas in the package is more likely to be blown out to the outside of the package due to the increase in the internal pressure of the package, and thus the manufacturing method according to the above (7) is particularly effective.

10 In the method of manufacturing the semiconductor device according to any one of the above (7) to (9), the adhesive before curing may have a thickness of 100 μm to 150 μm. The width of the first region in the second direction may be equal to or less than a half of the width of the second region in the second direction. A length of the first region in the first direction may be 1 to 1.5 times the width of the second region in the second direction. For example, since the top surface and the adhesive have such a size, the gas in the package is likely to be blown out to the outside of the package when the internal pressure of the package rises, and the uncured adhesive is likely to be drawn into the trace of blowing when the gas outside the package is sucked into the package through the trace of blowing. Thus, the effect of the manufacturing method according to (7) can be sufficiently achieved.

### Details of Embodiments of Present Disclosure

Specific examples of the present disclosure will be described below with reference to the accompanying drawings. The present disclosure is not limited to these examples, but is defined by the claims, and is intended to include all modifications within the meaning and scope equivalent to the claims. In the following description, the same elements will be denoted by the same reference numerals in the description of the drawings, and repeated description thereof will be omitted.

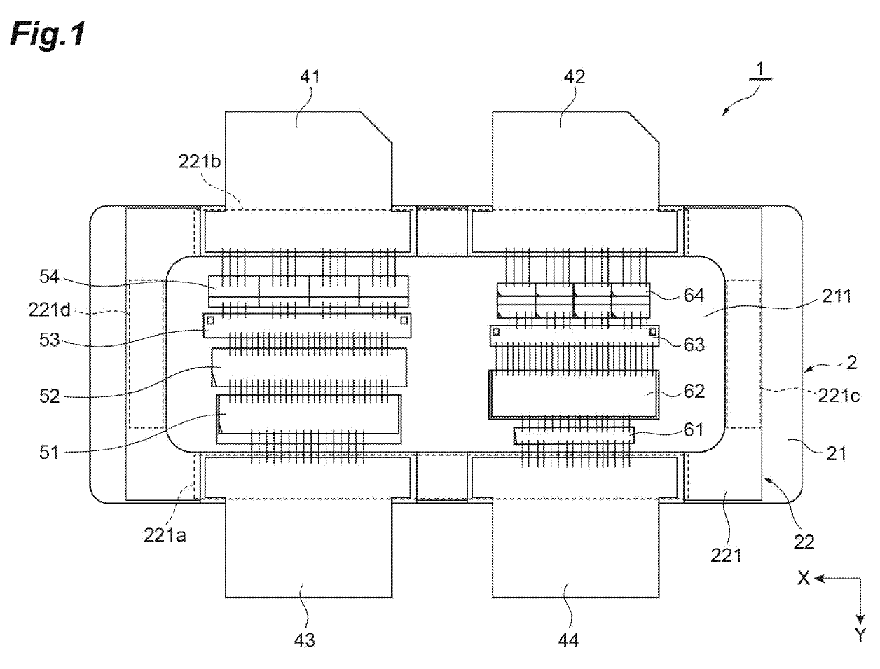

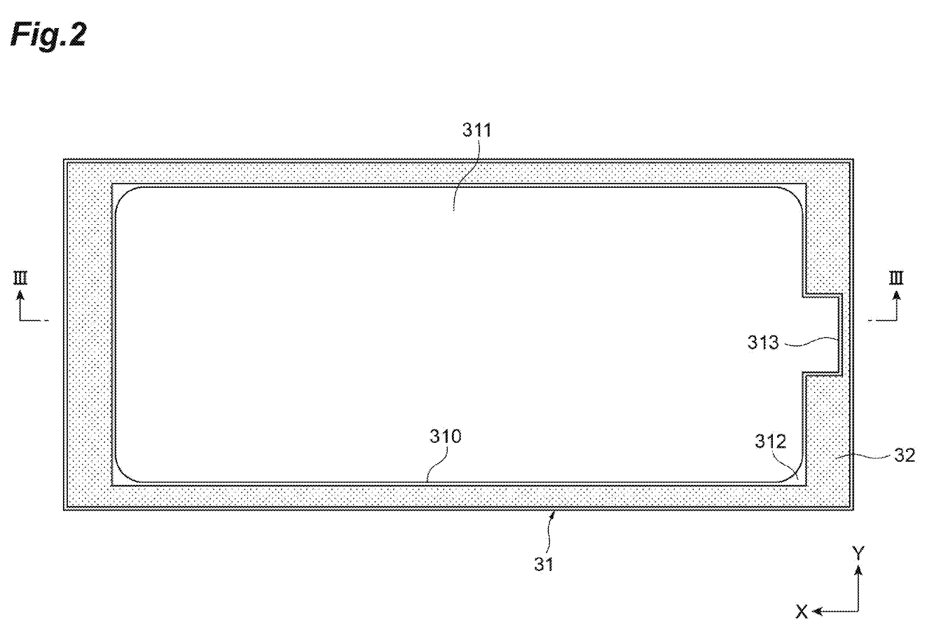

FIG. 1 is a plan view showing a semiconductor device 1 according to an embodiment of the present disclosure. FIG. 2 is a bottom plan view showing a cap 31 and an adhesive 32 included in the semiconductor device 1. In FIG. 1, the cap 31 and the adhesive 32 are not shown. The semiconductor device 1 includes a package having a package base 2 and the cap 31, the adhesive 32, multiplexing circuits 51 and 61, output matching circuits 52 and 62, FET chips 53 and 63, and input matching circuits 54 and 64. The FET chips 53 and 63 are semiconductor elements in the present embodiment.

As shown in FIG. 1, the package base 2 includes a base plate 21, a side wall 22 (first side wall), output leads 43 and 44, and input leads 41, 42. The base plate 21 is a plate-shaped member having a planar shape such as a substantially rectangular shape, and the long side thereof is along an X direction (second direction) and the short side thereof is along a Y direction (first direction) orthogonal to the X direction. The base plate 21 includes an electrically conductive material, for example, a metal such as copper (Cu). In one example, the base plate 21 is a copper plate. The base plate 21 has a mounting surface 211 that is flat.

The side wall 22 is a frame-shaped member having a planar shape such as a substantially quadrangular shape, is provided on the base plate 21 so as to surround the mounting surface 211, and is fixed to the base plate 21. One side of the side wall 22 is along the X direction, and the other side of the side wall 22 is along the Y direction. The side wall 22 includes an insulating material, for example, ceramic. In one example, the side wall 22 is made of ceramic. The side wall 22 has a top surface 221 along the XY plane. The top surface 221 is a surface of the side wall 22 opposite to the base plate 21. The top surface 221 includes a first portion 221a, a second portion 221b, a third portion 221c, and a fourth portion 221d. The first portion 221a and the second portion 221b extend along the X direction, and the third portion 221c and the fourth portion 221d extend along the Y direction. When viewed in the normal direction of the mounting surface 211, the mounting surface 211 is interposed between the first portion 221a and the second portion 221b in the Y direction. When viewed in the same direction, the mounting surface 211 is interposed between the third portion 221c and the fourth portion 221d in the X direction.

The output leads 43 and 44 and the input leads 41 and 42 are plate-like members having electrical conductivity, and are copper plates in one example. The output leads 43 and 44 are arranged side by side in the X direction on the first portion 221a of the top surface 221 of the side wall 22. The input leads 41 and 42 are arranged side by side in the X direction on the second portion 221b of the top surface 221 of the side wall 22.

The multiplexing circuits 51 and 61, the output matching circuits 52 and 62, the FET chips 53 and 63, and the input matching circuits 54 and 64 are mounted on the mounting surface 211 and surrounded by the side wall 22. The multiplexing circuit 51, the output matching circuit 52, the FET chip 53, and the input matching circuit 54 constitute an amplification circuit. A signal input terminal (gate) of the FET chip 53 is electrically connected to the input lead 41 via the input matching circuit 54. A signal output terminal (drain) of the FET chip 53 is electrically connected to the output lead 43 via the output matching circuit 52 and the multiplexing circuit 51. The multiplexing circuit 61, the output matching circuit 62, the FET chip 63, and the input matching circuit 64 constitute another amplification circuit. A signal input terminal (gate) of the FET chip 63 is electrically connected to the input lead 42 via the input matching circuit 64. A signal output terminal (drain) of the FET chip 63 is electrically connected to the output lead 44 via the output matching circuit 62 and the multiplexing circuit 61.

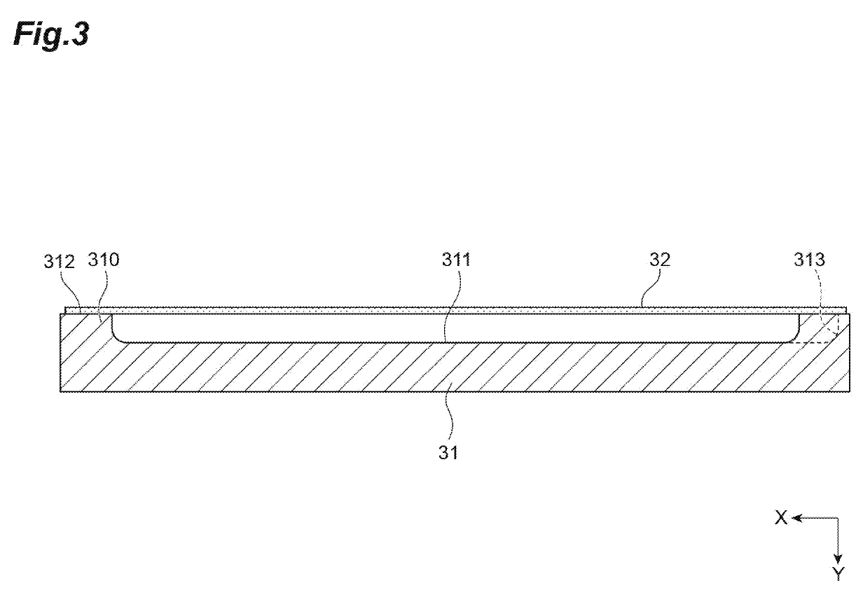

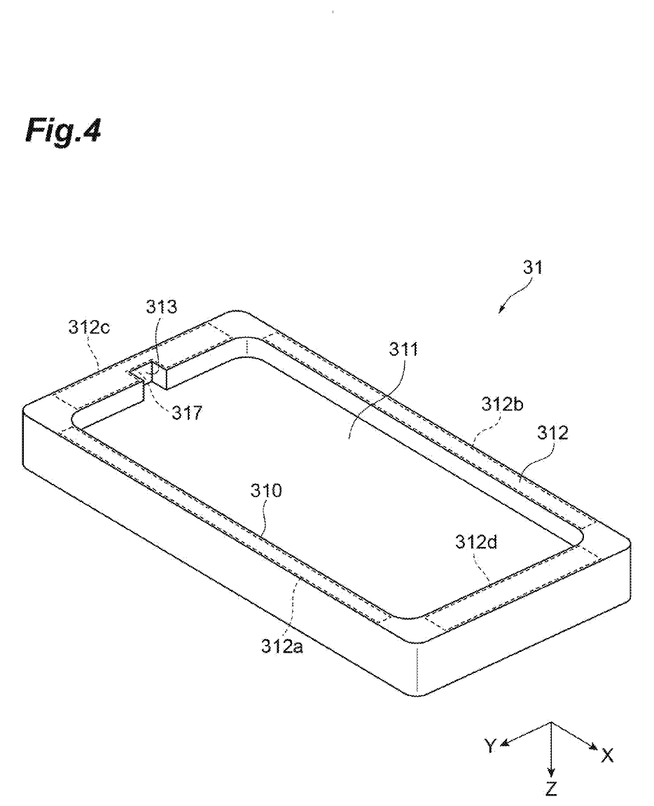

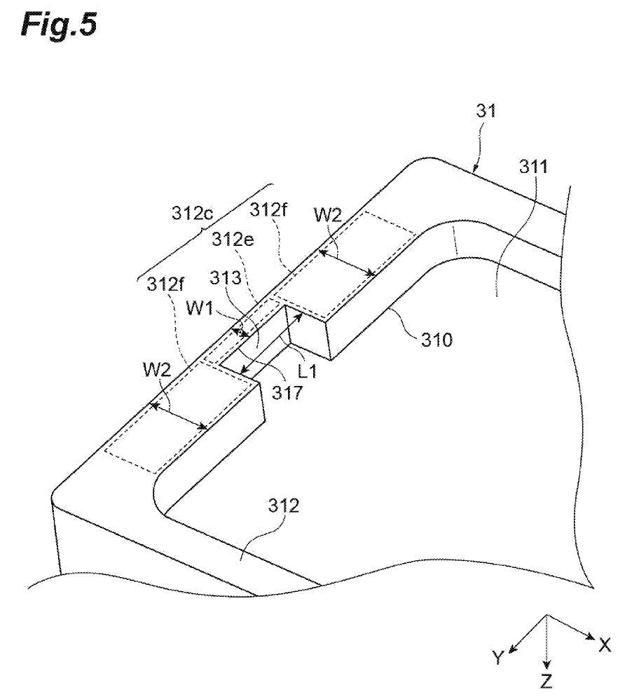

FIG. 3 is a cross-sectional view of the cap 31, taken along the line III-III shown in FIG. 2. FIG. 4 is a perspective view showing the cap 31. FIG. 5 is a perspective view showing a part of the cap 31 in an enlarged manner. The cap 31 includes an insulating material, for example, ceramic. In one example, the cap 31 is made of ceramic. The cap 31 is disposed on the package base 2 to form a closed hollow portion (cavity) between the cap 31 and the package base 2, and the FET chips 53 and 63 are housed in the hollow portion. As shown in FIGS. 2 to 5, the cap 31 is a substantially flat plate-shaped member and has a side wall 310 (second side wall) and an inner surface 311. The inner surface 311 is a flat surface and faces the mounting surface 211 of the base plate 21. The side wall 310 protrudes toward the base plate 21 so as to surround the inner surface 311, and faces the side wall 22 of the package base 2.

The side wall 310 has a top surface 312 along the XY plane, which faces the top surface 221 of the package base 2. The top surface 312 includes a first portion 312a, a second portion 312b, a third portion 312c, and a fourth portion 312d. The first portion 312a and the second portion 312b extend along the X direction, and the third portion 312c and the fourth portion 312d extend along the Y direction. When viewed in the normal direction (Z direction orthogonal to both the X direction and the Y direction) of the inner surface 311, the inner surface 311 is interposed between the first portion 312a and the second portion 312b in the Y direction. When viewed in the same direction, the inner surface 311 is interposed between the third portion 312c and the fourth portion 312d in the X direction.

As shown in FIG. 5, the third portion 312c includes a first region 312e and at least one (two in the illustrated example) second region 312f. The one second region 312f, the first region 312e, and the other second region 312f are arranged in this order along the extending direction of the third portion 312c, that is, the Y direction. A width W1 of the first region 312e in the X direction has a first size. A width W2 of the second region 312f in the X direction has a second size larger than the first size. In one example, the width W1 of the first region 312e is equal to or less than a half of the width W2 of the second region 312f. In addition, in one example, a length L1 of the first region 312e in the Y direction is 1 to 1.5 times the width W2 of the second region 312f.

In the illustrated example, the first region 312e is interposed between the two second regions 312f in the Y direction. Thus, the first region 312e and the two second regions 312f form a recess 317 (first recess) in the third portion 312c, which is recessed in a direction opposite to the hollow portion of the package. The planar shape of the recess 317 is, for example, rectangular. The recess 317 is formed by forming a recess 313, which is recessed in the direction opposite to the hollow portion of the package, in an inner surface of the side wall 310. The recess 313 may reach the inner surface 311 from the top surface 312, or does not have toreach the inner surface 311 from the top surface 312.

The adhesive 32 is provided between the top surface 221 of the side wall 22 and the top surface 312 of the side wall 310, and is provided over the entire periphery of the side wall 22 and the side wall 310. That is, the adhesive 32 is provided between the first portion 221a of the top surface 221 and the first portion 312a of the top surface 312. The adhesive 32 is provided between the second portion 221b of the top surface 221 and the second portion 312b of the top surface 312. The adhesive 32 is provided between the third portion 221c of the top surface 221 and the third portion 312c of the top surface 312. The adhesive 32 is provided between the fourth portion 221d of the top surface 221 and the fourth portion 312d of the top surface 312. The adhesive 32 adheres the side wall 22 to the side wall 310. The adhesive 32 includes, for example, a thermosetting resin. In this case, the viscosity of the adhesive 32 before curing at 150°C is, for example, 300,000 (mPa·s) to 500,000 (mPa·s). Alternatively, the adhesive 32 is, for example, an epoxy-based adhesive. In this case, the viscosity of the adhesive 32 before curing at 24°C is, for example, 90,000 (mPa·s) to 120,000 (mPa·s). A thickness of the adhesive 32 before curing in the Z direction is, for example, 100 μm to 150 μm.

The effect achieved by the semiconductor device 1 of the present embodiment described above will be described. In recent years, the technology in the field of information communication has been developed at a remarkable speed, and signals in a higher frequency band from a microwave band to a millimeter wave band have been handled. In order to handle such a signal in a high frequency band, a semiconductor element having excellent high frequency characteristics is required, and in addition, the high frequency characteristics vary greatly depending on a package in which the semiconductor element is mounted and a method of mounting the semiconductor element in the package. For example, the high-frequency characteristics of the semiconductor element may be deteriorated by the influence of moisture, heat, contamination, electromagnetic field, and the like outside the package. Thus, in order to protect the semiconductor elements (the FET chips 53 and 63 in the present embodiment) from those influences, the package base 2, on which the semiconductor elements are mounted, and the cap 31 are bonded to each other to hermetically seal the semiconductor elements, and a hollow portion is formed around the semiconductor elements. Then, in order to perform hermetic sealing, the cap 31 and the package base 2 are bonded to each other without a gap.

However, due to certain factors, the gas inside the hermetically-sealed package may expand, causing the internal pressure of the package to rise, and the gas inside the package may blow out to the outside of the package by passing through uncured portions of the adhesive 32. When such a phenomenon occurs, an opening, which is a trace of the gas blowing out, remains as a through hole even after the adhesive 32 is cured. Thus, the air-tightness of the package is impaired.

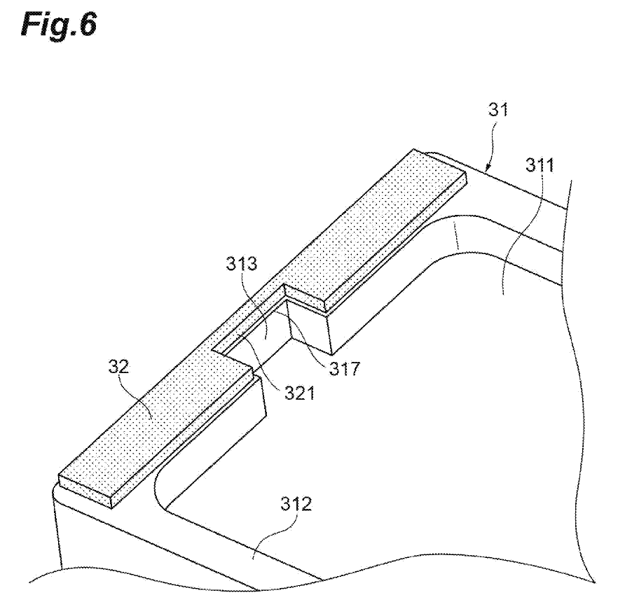

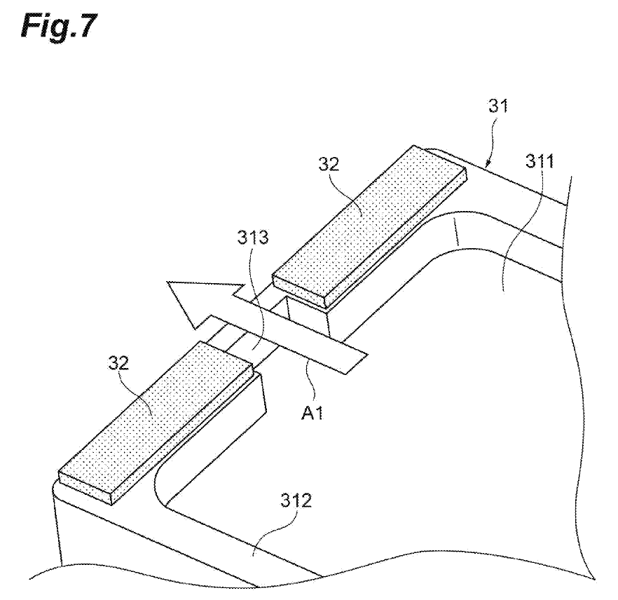

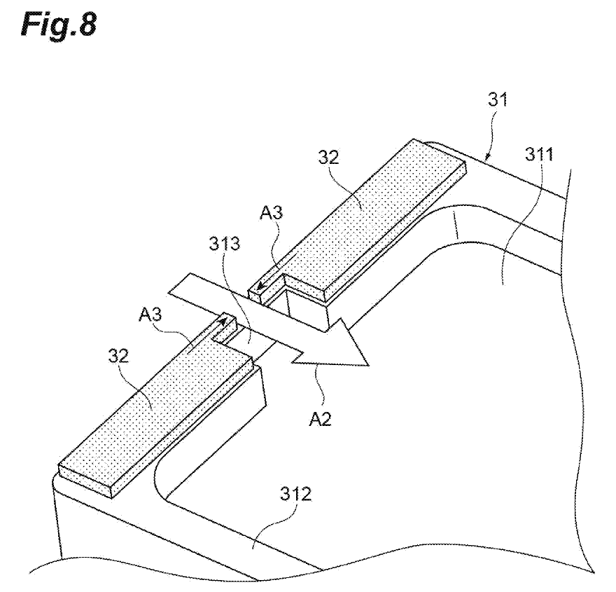

Each of FIGS. 6, 7, and 8 is a perspective view for describing an effect achieved by the semiconductor device 1. In the semiconductor device 1 of the present embodiment, the top surface 312 of the side wall 310 of the cap 31 includes the third portion 312c extending in the Y direction. The third portion 312c includes the first region 312e having the small width W1 and the second region 312f having the large width W2. As described above, since the top surface 312 of the side wall 310 has the first region 312e which is locally narrowed, a portion which is locally narrowed is also formed in the adhesive 32 as shown in FIG. 6. When the internal pressure of the package rises, as shown in FIG. 7, the gas is more likely to be blown out through the thinned portion (arrow A1). Thus, a position where the gas is blown out in the adhesive 32 can be limited. Further, after the gas is blown out, as shown in FIG. 8, when the internal pressure of the package is lowered and the gas outside the package is sucked into the package through the trace of blowing (through hole) (arrow A2), the uncured adhesive 32 on the second region 312f is drawn into the trace of blowing on the first region 312e (arrow A3), and the through hole is closed with the adhesive. This makes it possible to maintain the air-tightness of the package. As described above, according to the semiconductor device 1 according to the present embodiment, the air-tightness of the package can be maintained without providing the sheet as described in the patent literature on the cap 31.

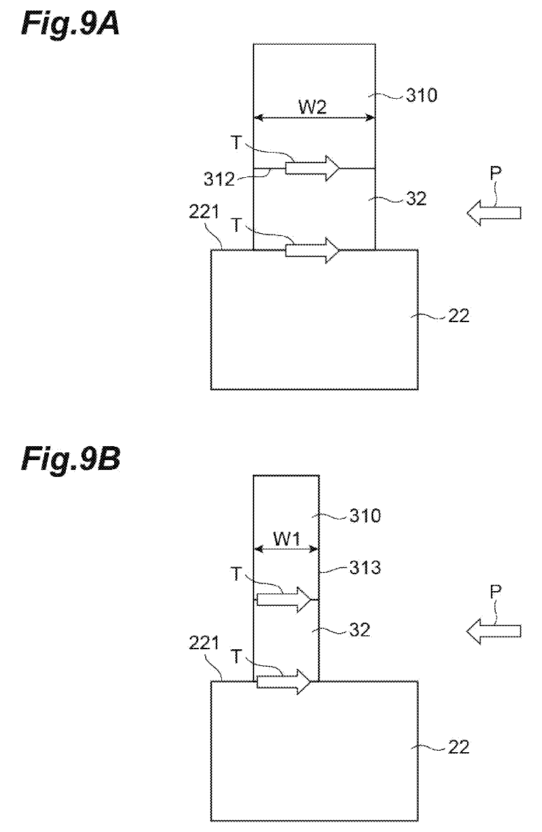

FIG. 9A and 9B are diagrams for describing the reason that gas is more likely to be blown out at a portion where the adhesive 32 is locally thinned. FIG. 9A is a diagram schematically showing a cross section of the side wall 310 and the adhesive 32 including the second region 312f. FIG. 9B is a diagram schematically showing a cross section of the side wall 310 at the recess 313 and the adhesive 32 including the first region 312e. When a pressure P is applied to the adhesive 32 due to the increase in the internal pressure of the package, a shear stress T is generated between the adhesive 32 and the side wall 310. The friction resistance between the adhesive 32 and the side wall 310 is proportional to the shear stress T and the width of an interface between the adhesive 32 and the side wall 310. That is, in the cross section including the first region 312e (FIG. 9B), the friction resistance is proportional to T × W1, and in the cross section including the second region 312f (FIG. 9A), the friction resistance is proportional to T × W2. Since the width W1 is smaller than the width W2, the friction resistance between the adhesive 32 and the side wall 310 in the cross section including the first region 312e is smaller than the friction resistance between the adhesive 32 and the side wall 310 in the cross section including the second region 312f. Thus, the adhesive 32 is more likely to be blown off by the pressure P in the portion of the adhesive 32 on the first region 312e, that is, the portion where the adhesive 32 is locally thinned. Thus, the gas is more likely to be blown out at the portion where the adhesive 32 is locally thinned.

As in the present embodiment, the third portion 312c may include two second regions 312f, and the first region 312e may be interposed between the two second regions 312f in the Y direction. The first region 312e and the two second regions 312f may form the recess 317, which is recessed in a direction opposite to the hollow portion (cavity) in the third portion 312c. In this case, a recess 321 is formed in the adhesive 32 on the recess 317 as shown in FIG. 6. When the internal pressure of the package rises, as shown in FIG. 7, gas is more likely to be blown out through the recess 321 of the adhesive 32 (arrow A1). Thus, the position where the gas is blown out in the adhesive 32 can be limited. Further, after the gas is blown out, as shown in FIG. 8, when the internal pressure of the package is lowered and the gas outside the package is sucked into the package through the trace of blowing (through hole) (arrow A2), the uncured adhesive 32 on the region adjacent to the recess 317 is drawn into the trace of blowing on the first region 312e (arrow A3), and the through hole is closed with the adhesive. This makes it possible to maintain the air-tightness of the package.

As in the present embodiment, the planar shape of the recess 317 may be rectangular. For example, when the recess 317 has such a shape, the blowing position of the gas in the adhesive 32 is more easily limited, and the through hole is likely to be closed with the adhesive when the gas is sucked into the package through the trace of blowing.

As described above, the adhesive 32 may include a thermosetting resin. In this case, the internal pressure of the package rises due to the temperature rise when the adhesive 32 is cured, and the gas in the package is more likely to blow out to the outside of the package by passing through the uncured adhesive 32. Thus, the configuration of the semiconductor device 1 of the present embodiment is particularly effective when the adhesive 32 contains a thermosetting resin.

When the adhesive 32 contains a thermosetting resin, the viscosity of the adhesive 32 before curing at 150°C may be 300,000 (mPa·s) to 500,000 (mPa·s). When the uncured adhesive 32 has such a viscosity, the gas in the package is likely to blow out to the outside of the package when the internal pressure of the package rises, and the uncured adhesive 32 is likely to be drawn into the trace of blowing when the gas outside the package is sucked into the package through the trace of blowing. Thus, the effect of the semiconductor device 1 of the present embodiment can be sufficiently achieved.

As described above, the adhesive 32 may be an epoxy-based adhesive. In this case, the adhesive 32 is cured by drying, but even in such a case, when the internal pressure of the package rises due to a rise in the ambient temperature or the like, the gas in the package blows out to the outside of the package. Thus, the configuration of the semiconductor device 1 of the present embodiment is effective.

When the adhesive 32 is an epoxy-based adhesive, the viscosity of the adhesive 32 before curing at 24°C may be 90,000 (mPa·s) to 120,000 (mPa·s). As described above, when the viscosity of the adhesive 32 is relatively small, the gas in the package is more likely to be blown out to the outside of the package due to the increase in the internal pressure of the package, and thus the configuration of the semiconductor device 1 of the present embodiment is particularly effective.

As in the present embodiment, the thickness of the adhesive 32 before curing may be 100 μm to 150 μm, the width W1 of the first region 312e may be equal to or less than a half of the width W2 of the second region 312f, and the length L1 of the first region 312e may be 1 to 1.5 times the width W2 of the second region 312f. For example, since the top surface 312 of the side wall 310 and the adhesive 32 have such a size, the gas in the package is likely to be blown out to the outside of the package when the internal pressure of the package rises, and the uncured adhesive 32 is likely to be drawn into the trace of blowing when the gas outside the package is sucked into the package through the trace of blowing. Thus, the effect of the semiconductor device 1 of the present embodiment can be sufficiently achieved.

Here, a method of manufacturing the semiconductor device 1 according to the present embodiment will be described. First, the package base 2 is placed on a temporary attaching stage, and the cap 31 provided with the adhesive 32 is temporarily placed on the package base 2. When the adhesive 32 contains a thermosetting resin, the temperature of the adhesive 32 is set to 90°C, and when the adhesive 32 is an epoxy-based adhesive, the temperature of the adhesive 32 is set to room temperature. At this time, the cap 31 is temporarily fixed to the package base 2 because the adhesive 32 is soft. Next, the expanding gas in the hollow portion (cavity) is released in a non-pressurized state. At this time, when the adhesive 32 contains a thermosetting resin, preheating (for example, 190°C, 20 seconds to 40 seconds) is performed. In this step, the adhesive 32 is melted and kept in a soft state.

Next, the package base 2 to which the cap 31 is temporarily attached is placed on a final attachment stage, a load (for example, 10 N) is applied to the cap 31 using a collet, and the adhesive 32 is crushed to hermetically seal the hollow portion. At the same time, the adhesive 32 is cured. When the adhesive 32 contains a thermosetting resin, the high temperature is maintained for a predetermined time (for example, 190°C, 110 seconds). Thereafter, the package is removed from the final attachment stage, and the adhesive 32 is dried. When the adhesive 32 contains a thermosetting resin, the adhesive 32 is cooled at the same time. The semiconductor device 1 of the present embodiment is manufactured by the above steps.

### First Modification

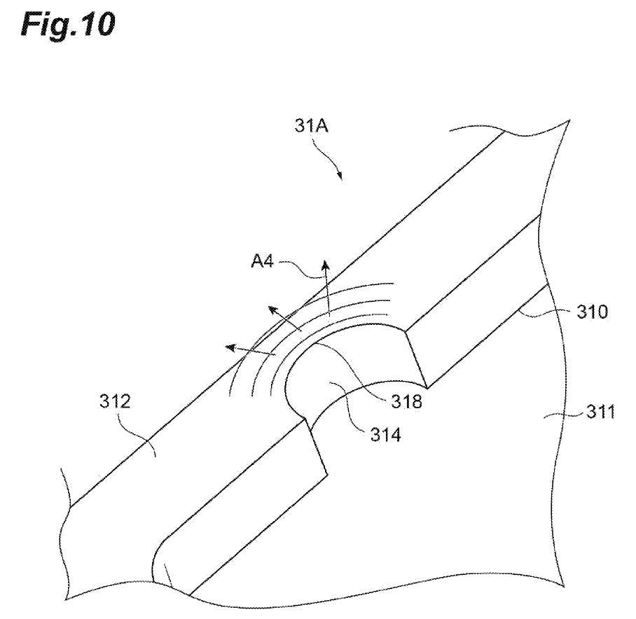

FIG. 10 is a perspective view showing a part of a cap 31A according to a first modification in an enlarged manner. In the cap 31A, a recess 318 (first recess) is formed in the top surface 312 of the side wall 310 instead of the recess 317 of the above embodiment. The recess 318 is recessed in a direction opposite to the hollow portion of the package. The recess 318 is also formed by the first region 312e and two second regions 312f (both shown in FIG. 5), as in the recess 317 of the above embodiment. The planar shape of the recess 318 is semicircular. The recess 318 is formed by forming a recess 314 having a semicircular planar shape in an inner surface of the side wall 310. The recess 314 may reach the inner surface 311 from the top surface 312, or does not have to reach the inner surface 311 from the top surface 312. In this modification, the gas inside the package is blown out in a direction spreading from the recess 318 toward the outside of the package as indicated by arrows A4.

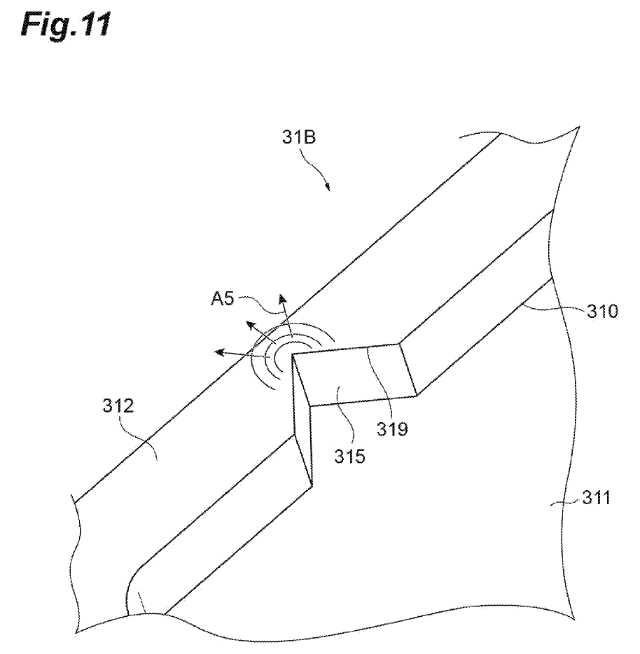

FIG. 11 is a perspective view showing a part of a cap 31B according to the first modification in an enlarged manner. In the cap 31B, a recess 319 (first recess) is formed in the top surface 312 of the side wall 310 instead of the recess 317 of the above embodiment. The recess 319 is recessed in the direction opposite to the hollow portion of the package. The recess 319 is also formed by the first region 312e and two second regions 312f (both shown in FIG. 5), as in the recess 317 of the above embodiment. The planar shape of the recess 319 is a tapered shape in which a width gradually decreases toward the outside of the package. The recess 319 is formed by forming a recess 315 having a tapered planar shape in the inner surface of the side wall 310. The recess 315 may reach the inner surface 311 from the top surface 312, or does not have to reach the inner surface 311 from the top surface 312. In this modification, the gas inside the package is blown out in a direction spreading from a tip of the recess 319 toward the outside of the package as indicated by arrows A5.

As in the present modification, the planar shape of the recess of the top surface 312 may be a tapered shape or a semicircular shape. For example, when the recess of the top surface 312 has such a shape, the blowing position of the gas in the adhesive 32 is more easily limited, and the through hole is more likely to be closed with the adhesive when the gas is sucked into the package through the trace of blowing.

### Second Modification

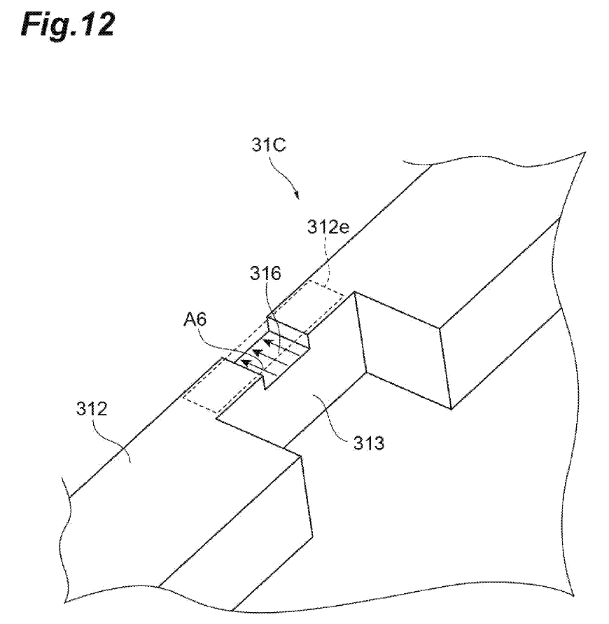

FIG. 12 is a perspective view showing a part of a cap 31C according to a second modification in an enlarged manner. In the cap 31C, a recess 316 recessed toward the inner surface 311 is formed in the first region 312e of the top surface 312 of the side wall 310 (in other words, in a direction opposite to the package base 2). In this case, a thickness of a portion of the adhesive 32 provided on the recess 316 is increased, and the portion is more likely to be blown off by the internal pressure of the package, so that the blowing position of the gas in the adhesive 32 is more easily limited. In this modification, the gas inside the package is blown out toward the outside of the package over the recess 316 as indicated by arrows A6.

### Third Modification

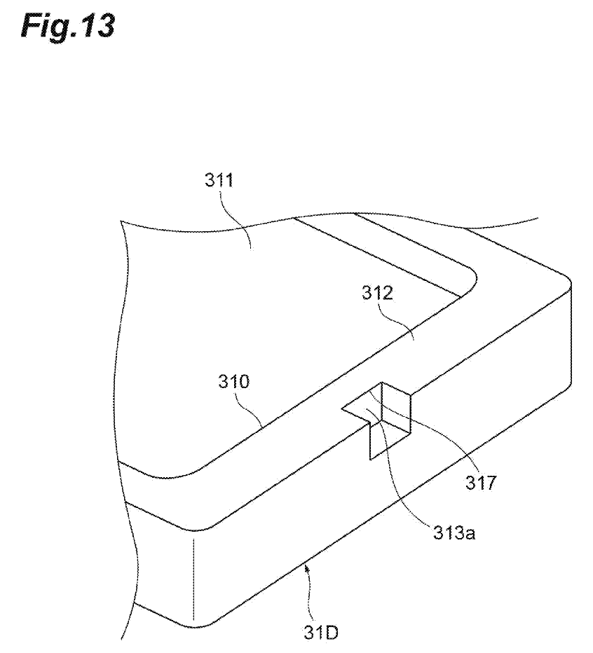

FIG. 13 is a perspective view showing a part of a cap 31D according to a third modification in an enlarged manner. In the cap 31D, the recess 317 of the top surface 312 is recessed toward the hollow portion of the package, not in the direction opposite to the hollow portion of the package. The recess 317 is formed by forming a recess 313a in an outer surface of the side wall 310. The planar shape of the recess 317 is not limited to a rectangular shape as shown in FIG. 13, and may be various shapes such as a semicircular shape shown in FIG. 10 or a tapered shape shown in FIG. 11.

As in the present modification, the recess of the top surface 312 may be recessed toward the hollow portion of the package. Even in this case, the same effect as that of the above embodiment can be achieved.

### Fourth Modification

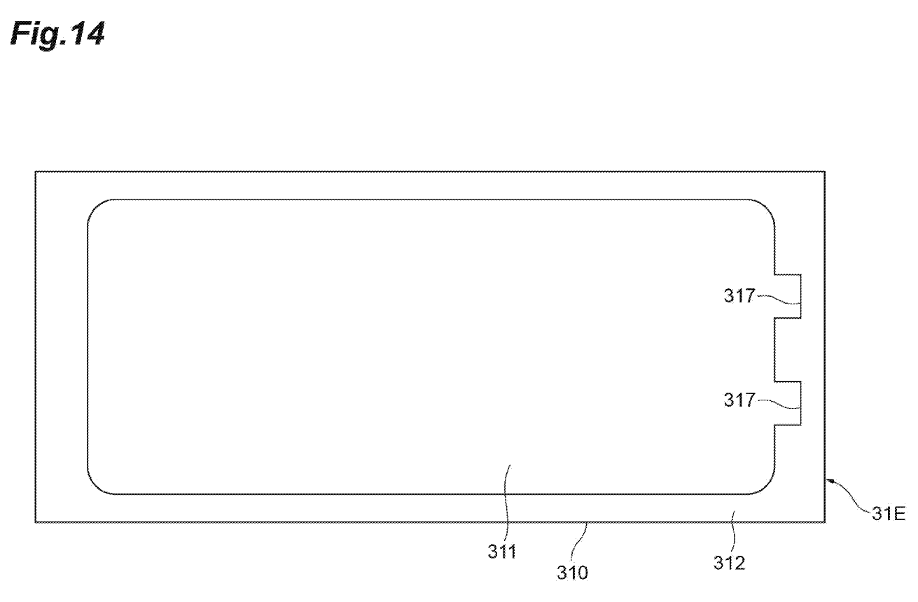

FIG. 14 is a bottom plan view showing a cap 31E according to a fourth modification. In the cap 31E, the top surface 312 has another recess 317 (second recess) in addition to the recess 317 (first recess) of the above embodiment. The shape of another recess 317 is the same as that of the recess 317 of the above embodiment. In addition, the recesses 317 may have a configuration according to any one of the above-described first modification to third modification.

As in the present modification, the top surface 312 may further have another recess 317 that is recessed toward the hollow portion of the package or recessed in the direction opposite to the hollow portion. In this case, the plurality of recesses 317 are provided in the top surface 312, thereby forming a plurality of recesses 321 (see FIG. 6) in the adhesive 32. This allows the gas to be efficiently blown out from the inside of the package to the outside of the package, and the internal pressure of the package can be quickly reduced.

### Fifth Modification

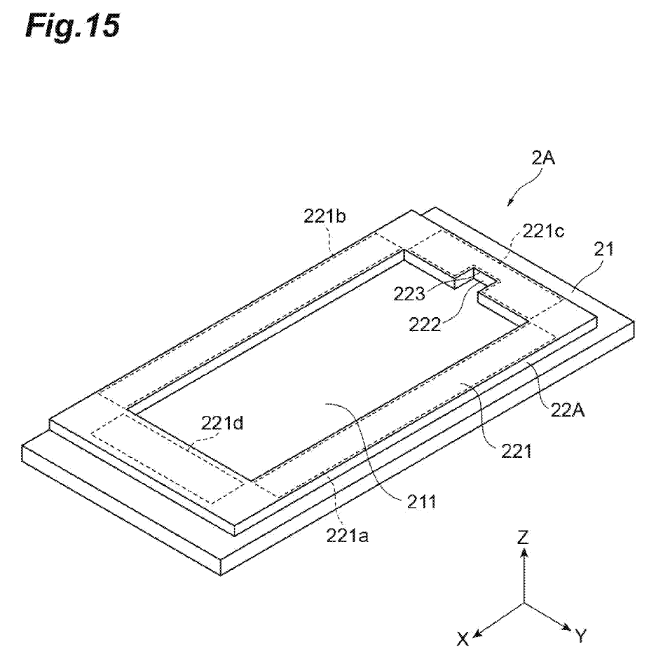

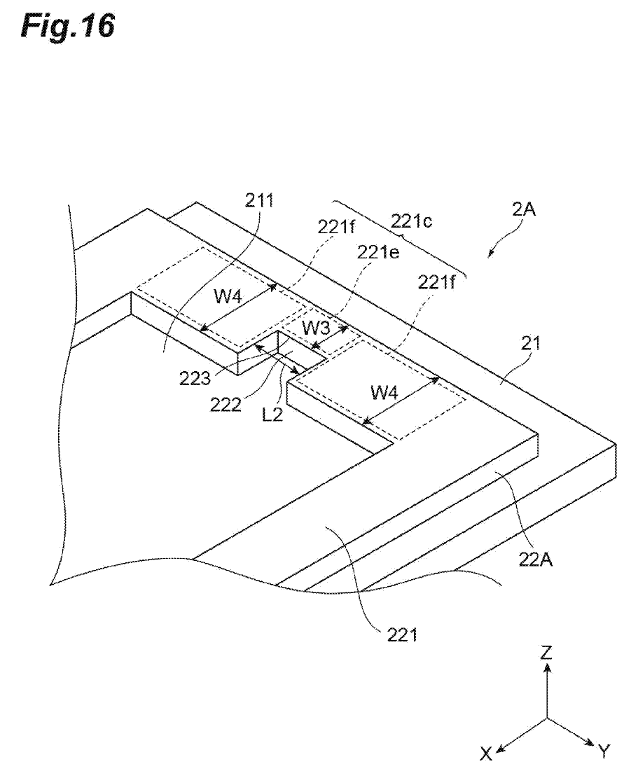

FIG. 15 is a perspective view showing a package base 2A according to a fifth modification. FIG. 16 is a perspective view showing a part of the package base 2A in an enlarged manner. The package base 2A has a side wall 22A instead of the side wall 22 of the above embodiment. The top surface 221 of the side wall 22A has the first portion 221a, the second portion 221b, the third portion 221c, and the fourth portion 221d, as in the side wall 22 of the above embodiment. However, unlike the above embodiment, the third portion 221c includes a first region 221e and at least one (two in the illustrated example) second region 221f. The one second region 221f, the first region 221e, and the other second region 221f are arranged in this order along the extending direction of the third portion 221c, that is, the Y direction. A width W3 of the first region 221e in the X direction has a first size. A width W4 of the second region 221f in the X direction has a second size larger than the first size. In one example, the width W3 of the first region 221e is equal to or less than a half of the width W4 of the second region 221f. In addition, in one example, a length L2 of the first region 221e in the Y direction is 1 to 1.5 times the width W4 of the second region 221f.

In the illustrated example, the first region 221e is interposed between the two second regions 221f in the Y direction. Thus, the first region 221e and the two second regions 221f form a recess 223 (first recess) in the third portion 221c, which is recessed in the direction opposite to the hollow portion of the package. The planar shape of the recess 223 is, for example, rectangular. The recess 223 is formed by forming a recess 222, which is recessed in the direction opposite to the hollow portion of the package, in the inner surface of the side wall 22A. The recess 222 may reach the mounting surface 211 from the top surface 221, or does not have to reach the mounting surface 211 from the top surface 221.

As in the present modification, the third portion 221c may include two second regions 221f, and the first region 221e may be interposed between the two second regions 221f in the Y direction. The first region 221e and the two second regions 221f may form the recess 223, which is recessed in the direction opposite to the hollow portion (cavity) in the third portion 221c. In this case, a recess is also formed in the adhesive 32 on the recess 223. When the internal pressure of the package rises, the gas is more likely to be blown out through the recess of the adhesive 32. Thus, a position where the gas is blown out in the adhesive 32 can be limited. Further, when the internal pressure of the package is lowered after the gas is blown out and the gas outside the package is sucked into the package through the trace of blowing (through hole), the uncured adhesive 32 on the region adjacent to the recess 223 is drawn into the trace of blowing on the first region 221e, and the through hole is closed with the adhesive. This makes it possible to maintain the air-tightness of the package.

In this modification, the recess 317 (or the recess of the modification) may be formed in the top surface 312 of the cap 31, or the recess 317 does not have to be formed in the top surface 312 of the cap 31.

The semiconductor device and the method of manufacturing the semiconductor device according to the present disclosure are not limited to the above-described embodiments, and various modifications may be made. For example, in the above embodiments and each modification, the recess having rectangular shape, tapered shape, or semicircular shape is illustrated, but the shape of the recess is not limited thereto. In addition, although a thermosetting resin and an epoxy-based adhesive are exemplified as the adhesive, the type of the adhesive is not limited thereto. In the above embodiments and modifications, the portion of the side wall extending in the Y direction includes the first region and the second region, but the portion (the first portion or the second portion) of the side wall extending in the X direction may include the first region and the second region.

What is claimed is:

1. A semiconductor device comprising:
a semiconductor element;
a package base having a mounting surface on which the semiconductor element is disposed and a first side wall surrounding the semiconductor element, the first side wall having a top surface;
a cap disposed on the package base to form a closed hollow portion between the cap and the package base and to house the semiconductor element in the hollow portion, and having a second side wall facing the first side wall of the package base, the second side wall having a top surface facing the top surface of the package base; and
an adhesive provided between the top surface of the first side wall and the top surface of the second side wall to adhere the first side wall to the second side wall,
wherein at least one of the top surface of the first side wall or the top surface of the second side wall includes a portion extending in a first direction, and
wherein the portion includes a first region whose width in a second direction orthogonal to the first direction has a first size, and at least one second region whose width in the second direction has a second size larger than the first size.

2. The semiconductor device according to claim 1,
wherein the at least one second region includes two second regions, and the first region is interposed between the two second regions in the first direction, and
wherein the first region and the two second regions form a first recess in the portion, the first recess being recessed toward the hollow portion or recessed in a direction opposite to the hollow portion.

3. The semiconductor device according to claim 2,
wherein the first recess has a planar shape that is rectangular, tapered, or semicircular.

4. The semiconductor device according to claim 2,
wherein the portion further includes a second recess that is recessed toward the hollow portion or recessed in a direction opposite to the hollow portion.

5. The semiconductor device according to claim 1,
wherein the adhesive includes a thermosetting resin.

6. The semiconductor device according to claim 1,
wherein the adhesive is an epoxy-based adhesive.

7. A method of manufacturing the semiconductor device according to claim 1, the method comprising:
mounting the semiconductor element on the package base;
applying the adhesive before curing to the top surface of the first side wall of the package base or the top surface of the second side wall of the cap; and
mounting the cap on the package base.

8. The method of manufacturing the semiconductor device according to claim 7,
wherein the adhesive before curing has a viscosity of 300,000 (mPa·s) to 500,000 (mPa·s) at 150°C.

9. The method of manufacturing the semiconductor device according to claim 7,
wherein the adhesive before curing has a viscosity of 90,000 (mPa·s) to 120,000 (mPa·s) at 24°C.

10. The method of manufacturing the semiconductor device according to claim 7,
wherein the adhesive before curing has a thickness of 100 μm to 150 μm,
wherein the width of the first region in the second direction is equal to or less than a half of the width of the second region in the second direction, and
wherein a length of the first region in the first direction is 1 to 1.5 times the width of the second region in the second direction.
